(19) United States
(12) Patent Application Publication
(10) Pub. No.: US 2015/0031155 A1
(43) Pub. Date: Jan. 29, 2015

(54) DEPOSITION APPARATUS AND METHOD OF MANUFACTURING ORGANIC LIGHT EMITTING DISPLAY APPARATUS BY USING THE SAME

(71) Applicant: SAMSUNG DISPLAY CO., LTD., Yongin-City (KR)

(72) Inventors: Chang-Woo Shim, Gyeonggi-Do (KR); Jae-Hyun Kim, Gyeonggi-Do (KR); Sung-Chul Kim, Gyeonggi-Do (KR)

(73) Assignee: SAMSUNG DISPLAY CO., LTD., Yongin-City (KR)

(21) Appl. No.: 14/148,996

(22) Filed: Jan. 7, 2014

(30) Foreign Application Priority Data
Jul. 24, 2013 (KR) 10-2013-0087602

(51) Int. Cl. H01L 51/56; H01L 51/00

(52) U.S. Cl. CPC H01L 51/56; H01L 51/0003
USPC 438/34; 118/620

(57) ABSTRACT

A deposition apparatus includes a stage and a deposition module. The stage holds a substrate. The deposition module faces the substrate. The stage relatively moves in a direction relative to the deposition module. The deposition module includes a first feeding unit and a first light exposure unit. The first feeding unit sprays a first raw material toward the substrate. The first light exposure unit is disposed on at least one side of the first feeding unit and provides light to the at least one raw material sprayed on the substrate.

### CROSS-REFERENCE TO RELATED APPLICATION

This application claims priority under 35 U.S.C. §119 to Korean Patent Application No. 10-2013-0087602, filed on Jul. 24, 2013 in the Korean Intellectual Property Office, the disclosure of which is incorporated herein by reference in its entirety.

### TECHNICAL FIELD

The present invention relates to a deposition apparatus and a method of manufacturing an organic light emitting display apparatus by using the same.

### DISCUSSION OF RELATED ART

Organic Light Emitting Diode Displays (OLEDs) may be classified into passive matrix OLEDs in which each pixel has no switching element, and active matrix OLEDs in which each pixel has a switching element formed by using a thin film transistor (TFT). The structure of active matrix OLEDs prevents an organic light-emitting unit formed of an organic material from becoming oxidized or deteriorating due to contact with oxygen and moisture using an encapsulating layer. The encapsulating layer seals the organic light-emitting unit, thereby preventing the organic light-emitting unit from being oxidized.

### SUMMARY

According to an exemplary embodiment of the present invention, a deposition apparatus includes a stage and a deposition module. The stage holds a substrate. The deposition module faces the substrate. The stage relatively moves in a direction relative to the deposition module. The deposition module includes a first feeding unit and a first light exposure unit. The first feeding unit sprays a first raw material toward the substrate. The first light exposure unit is disposed on at least one side of the first feeding unit and provides light to the at least one raw material sprayed on the substrate.

According to an exemplary embodiment of the present invention, a deposition apparatus includes a chamber, a stage, and a deposition module. The stage and the deposition module are positioned in the chamber. The stage holds a substrate. The deposition module faces the substrate. The stage relatively moves in a direction relative to the deposition module, The deposition module includes a plurality of feeding units and a plurality of light exposure units. Each feeding unit and each light exposure unit are alternately arranged along the direction. Each feeding unit sprays a raw material toward the substrate. Each light exposure unit provides light to the raw material sprayed on the substrate.

According to an exemplary embodiment of the present invention, a method of manufacturing an organic light emitting display apparatus is provided. A substrate is loaded on a stage. The stage is relatively moved relative to a deposition module between time T1 and time T2. The deposition module sprays a first raw material and a second raw material to the substrate. The deposition module is controlled to spray, at the time T1, the first raw material on a first part of the substrate. The deposition module is controlled to spray, at the time T2, the second raw material on first material deposited on the first part of the substrate. The deposition module is controlled to spray, at the time T2, the first raw material on a second part of the substrate. The deposition module is controlled to provide, immediately after the time T1 and before the time 12, light to the first material deposited on the first part of the substrate, The time T1 precedes the time T2.

### BRIEF DESCRIPTION OF THE DRAWINGS

These and other features of the present invention will become more apparent by describing in detail exemplary embodiments thereof with reference to the accompanying drawings of which:

FIG. 1 shows a deposition apparatus according to an exemplary embodiment of the present invention;

FIGS. 2A and 2B are schematic views of the stage and deposition module of FIG. 1;

FIG. 3 is an expanded view of a portion of FIG. 1;

FIGS. 4 to 6 shows various arrangements of a stage and a deposition module of a deposition apparatus according to an exemplary embodiment of the present invention;

FIG. 7 shows a deposition apparatus according to an exemplary embodiment of the present invention;

FIGS. 8A to 8C are schematic views of the stage and deposition module of FIG. 7;

FIG. 9 shows various arrangements of a stage and a deposition module of a deposition apparatus according to an exemplary embodiment of the present invention;

FIG. 10 is a schematic cross-sectional view of an organic light-emitting display device manufactured using a deposition apparatus according to an exemplary embodiment of the present invention; and

FIG. 11 is an expanded view of portion F of FIG. 10.

### DETAILED DESCRIPTION OF THE EXEMPLARY EMBODIMENTS

Exemplary embodiments of the present invention will be described below in detail with reference to the accompanying drawings. However, the present invention may be embodied in different forms and should not be construed as limited to the embodiments set forth herein. In the drawings, the thickness of layers and regions may be exaggerated for clarity. It will also be understood that when an element is referred to as being “on” another element or substrate, it may be directly on the other element or substrate, or intervening layers may also be present. Like reference numerals may refer to the like elements throughout the specification and drawings,

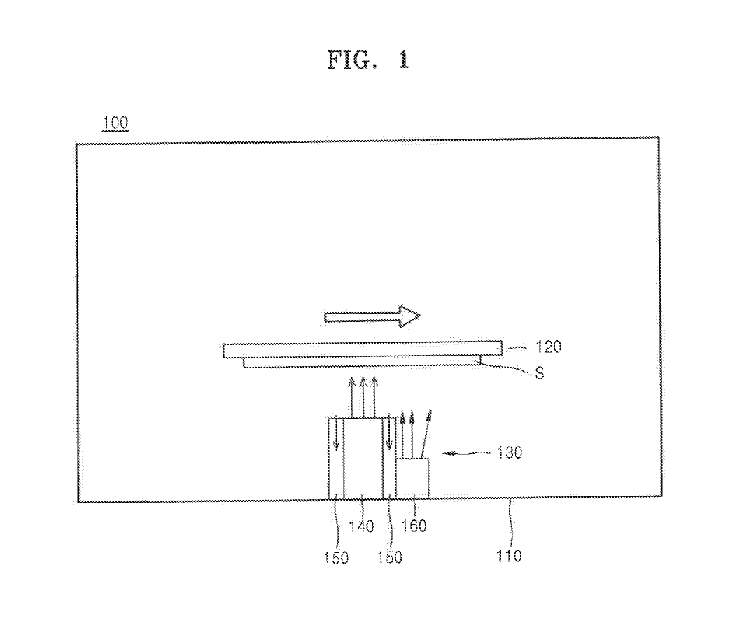

FIG. 1 shows a deposition apparatus according to an exemplary embodiment of the present invention.

Referring to FIG. 1, a deposition apparatus 100 according to an exemplary embodiment of the present invention includes a chamber 110, a stage 120, and a deposition module 130. The stage 120 and the deposition module 130 are arranged in the chamber 110.

The chamber 110 includes a space in which a substrate S is processed. The space may be sufficiently wide to allow the substrate S to be housed and processed therein. The space may also allow the substrate S to move in the chamber 110 in a direction represented by an arrow. The chamber 110 may have, but is not limited to, a cylindrical or a hexahedronal shape. The chamber 110 may have any shape that corresponds to the shape of the substrate S. Although not shown, an opening for loading and unloading the substrate S may be formed in at least one side of the chamber 110.

A stage 120 is arranged in the chamber 110. The substrate S is arranged on and supported by the stage 120. While the substrate S is on the stage 120, the stage 120 may move in a certain direction, for example, in a length direction of the substrate, in the chamber 110.

The deposition module 130 is arranged under the stage 120 to face the substrate S. The deposition module 130 and the stage 120 may move relative to each other.

The deposition module 130 includes a feeding unit 140, a discharge unit 150, and a light exposure unit 160.

The feeding unit 140 sprays at least one raw material toward the substrate S. The feeding unit 140 may spray a gaseous raw material for depositing the raw material on the substrate S. For example, the raw material may include a monomer to form an organic layer on the substrate S. The raw material may also be sprayed toward a layer formed on the substrate S.

The light exposure unit 160 is installed on at least one side of the feeding unit 140 and emits light, for example, ultraviolet rays toward the substrate to cure the raw material. The meaning of cure may be defined as a causing the sprayed raw material to be hardended. The light exposure unit 160 is arranged in the downstream part of the moving path of the stage 120 with respect to the deposition module 130. Such downstream arrangement of the light exposure unit 160 enables the light exposure unit 160 to cure the sprayed raw material after the raw material is sprayed on the substrate S. Thus, it is possible to prevent the sprayed raw material from flowing before the raw material is cured at the correct part of the substrate S. The light exposure unit 160 may include, but is not limited to, an ultraviolet lamp or a light-emitting diode.

The discharge unit 150 is arranged around the feeding unit 140 and discharges the raw material that is not deposited on the substrate S. While the discharge unit 150 moves in the direction represented by an arrow, the remaining raw material not deposited on the substrate S is discharged from the chamber 110. The discharge unit 150 is arranged at both sides of the feeding unit 140. However, the embodiment is not limited thereto and the discharge unit 150 may fully or partially wrap around the feeding unit 140.

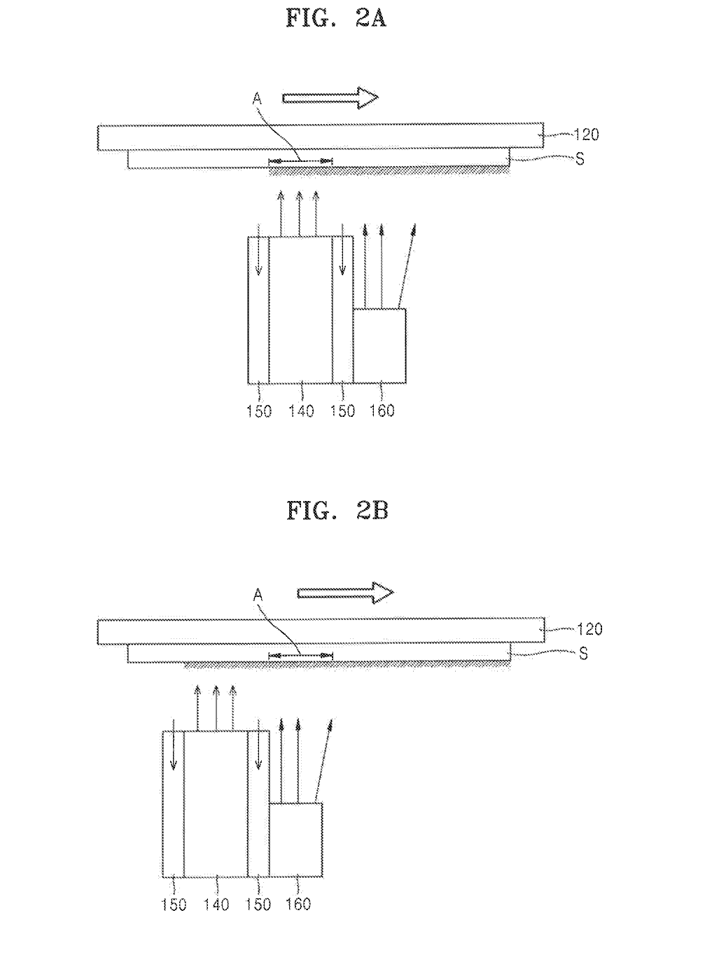

FIGS. 2A and 2B are schematic views of the stage and deposition module of FIG. 1. Referring to FIGS. 2A and 2B, the stage 120 moves in one direction (unidirectionally) with respect to the deposition module 130, and the feeding unit 140 of the deposition module 130 sprays the raw material toward the substrate S.

Part of the raw material sprayed toward the substrate S is deposited on the substrate S but other part thereof is not deposited on the substrate S and may remain suspended in the chamber 110. This raw material that remains suspend in the chamber 110 may be deposited on the nozzle of the feeding unit 140, the light exposure unit 160, and the inner wall of the chamber 110, which may decrease the deposition efficiency. The discharge unit 150 is arranged around the feeding unit 140 to discharge the sprayed raw material not deposited on the substrate S from the chamber 110 before the sprayed raw material is deposited on other parts. Thus, the arrangement of the discharge unit 150 increases the deposition efficiency.

Referring to FIG. 2A, the feeding unit 140 sprays the raw material toward the section A of the substrate S. The stage 120 moves in the direction along the arrow, and thus the section A of the substrate S on which the raw material is deposited is positioned to face the light exposure unit 160 as shown in FIG. 2B. The light exposure unit 160 emits ultraviolet rays toward the section A on which the raw material is deposited and cures the raw material. As such, by curing the raw material immediately after spraying the same, it is possible to increase the deposition efficiency.

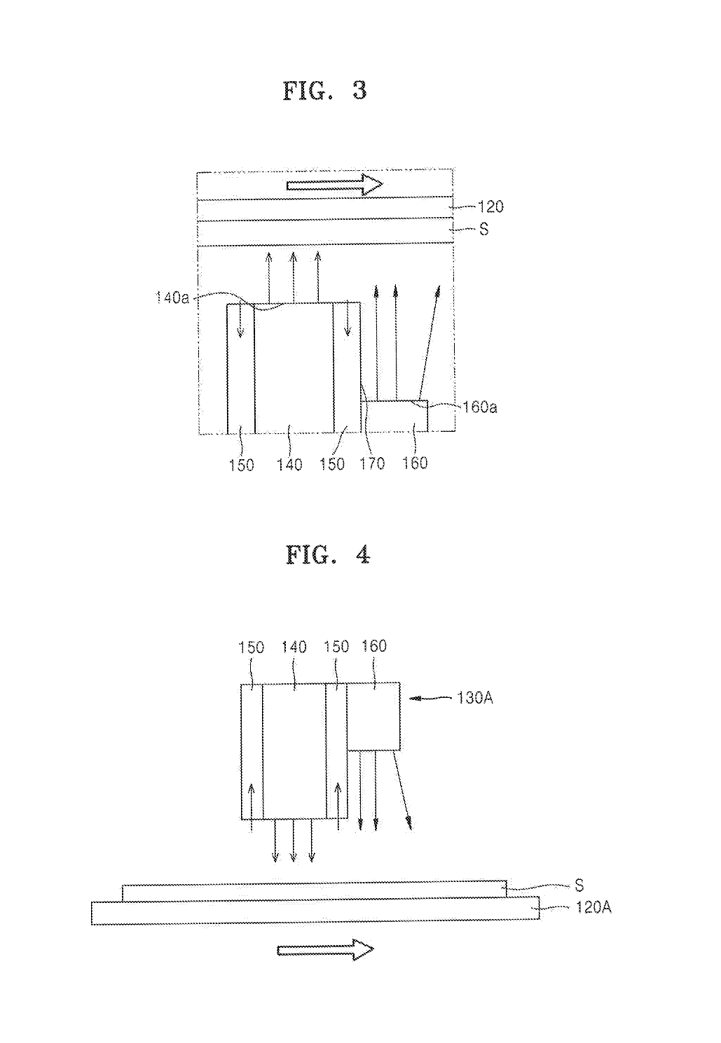

FIG. 3 is an expanded view of a portion of FIG. 1. Referring to FIG. 3, the light exposure unit 160 is installed at one side of the discharging unit 150. The discharging unit 150 and the light exposure unit 160 have different heights from each other. For example, an end 160a of the light exposure unit 160 is further away from the substrate S compared to the end 140a of the discharging unit 150. Thus, such different heights of the discharging unit 150 and the light exposure unit 160 may prevent the raw material sprayed from the feeding unit 140 from becoming cured by the light emitted from the light exposure unit 160 before the raw material sprayed from the feeding unit 140 reaches the substrate S. A sidewall 170 of the discharge unit 150, defined by the different heights, serves to prevent the light exposure unit 160 from curing the raw material flying toward the substrate S. The feeding unit 140 and the discharging unit 150 have substantially the same height, and the discharging unit is positioned between the feeding unit 140 and the light exposure unit 160. The structure of the discharge unit 150 is not limited thereto, and may be implemented in various forms. The light provided from the light exposure unit 160 may be blocked in various ways. For example, although not shown, the light exposure unit 160 may include a structure for blocking light protruding toward the substrate S at the edge of the light exposure unit 160.

FIGS. 4 to 6 show various arrangements of a stage and a deposition module of a deposition apparatus according to an exemplary embodiment of the present invention. For the convenience of description, a chamber corresponding to the chamber 110 of FIG. 1 is not shown in FIGS. 4 to 6 and related descriptions are omitted.

In the above-described embodiment, the stage 120 is arranged in an upper area of the chamber 110 and the deposition module 130 is arranged in a lower area of the chamber 110, and the stage 120 moves relative to the deposition module 130. However, the arrangement and relative movement of the stage 120 and the deposition module 130 are not limited thereto and may be changed.

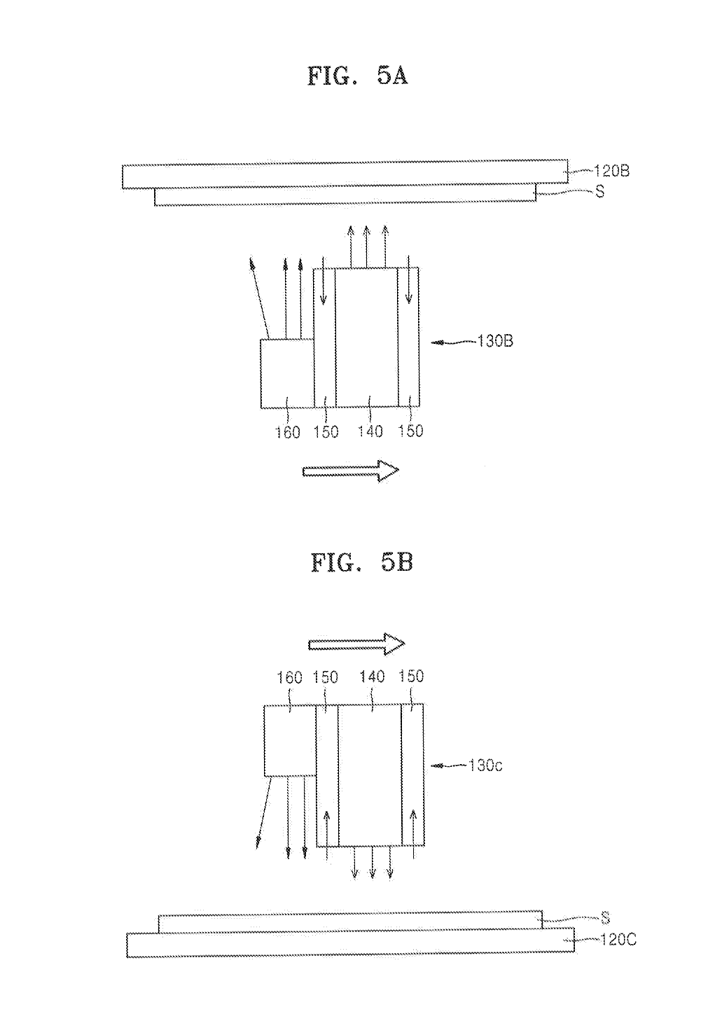

For example, referring to FIG. 4, the substrate S is arranged on a top surface of a stage 120A, and the feeding unit 140 sprays a raw material downwardly toward the substrate S. Referring to FIGS. 5A and 5B, a stage 120B or 120C is fixed and a deposition module 130B or 130C move relative to the stage 120B or 120C in a direction along an arrow. Moreover, although not shown, the stages 120 and 120A to 120C and the deposition modules 130 and 130A to 130C may all be movable.

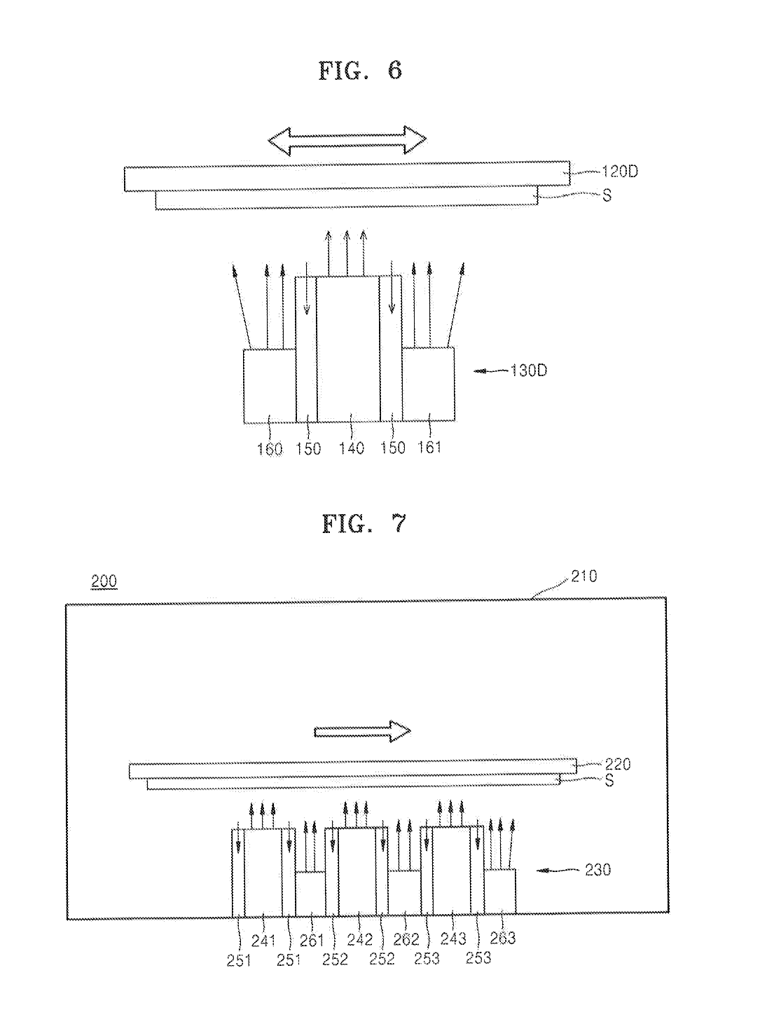

On the other hand, the stage 120 and the deposition module 130, and 130A to 130C relatively move in one direction (unidirectional motion) in the exemplary embodiments as described above. However, the present invention is not limited thereto, and the stage 120D and a deposition module 130D may relatively move in two directions (bidirectional motion) as shown in FIG. 6. In the latter case, since the position of the downstream part of the relative movement path varies according to a movement direction when the feeding unit 140 is in a reference position, light exposure units 160 and 161 are arranged at both sides of the feeding unit 140 as shown in FIG. 6.

FIG. 7 shows a deposition apparatus according to an exemplary embodiment of the present invention.

Referring to FIG. 7, a deposition apparatus 200 includes a chamber 210, a stage 220, and a deposition module 230. The chamber 210 and the stage 220 are substantially the same as those described in the foregoing embodiment.

The deposition module 230 includes a plurality of feeding units 241 to 243, a plurality of discharge units 251 to 253, and a plurality of light exposure units 261 to 263. For the convenience of description, three feeding units 241 to 243, three discharge units 251 to 253, and three light exposure units 261 to 263 are arranged. The deposition module 230 is not limited thereto, and may include two, four, or more feeding units, discharge units, and light exposure units, for example.

The feeding units 241 to 243, the discharge units 251 to 253, and the light exposure units 261 to 263 are successively arranged in a length direction of a substrate S. The length direction of the substrate S is defined as a direction parallel to a relative movement path between the substrate S and the deposition module 230. While the stage 220 supporting the substrate S moves relative to the deposition module 230, spraying, discharge, and curing of a raw material are repetitively performed. Since each of the spraying and curing of the raw material is performed several times along the length direction of the substrate S, it is possible to decrease a process time and prevent the nozzles of the feeding units 241 to 243 from being clogged.

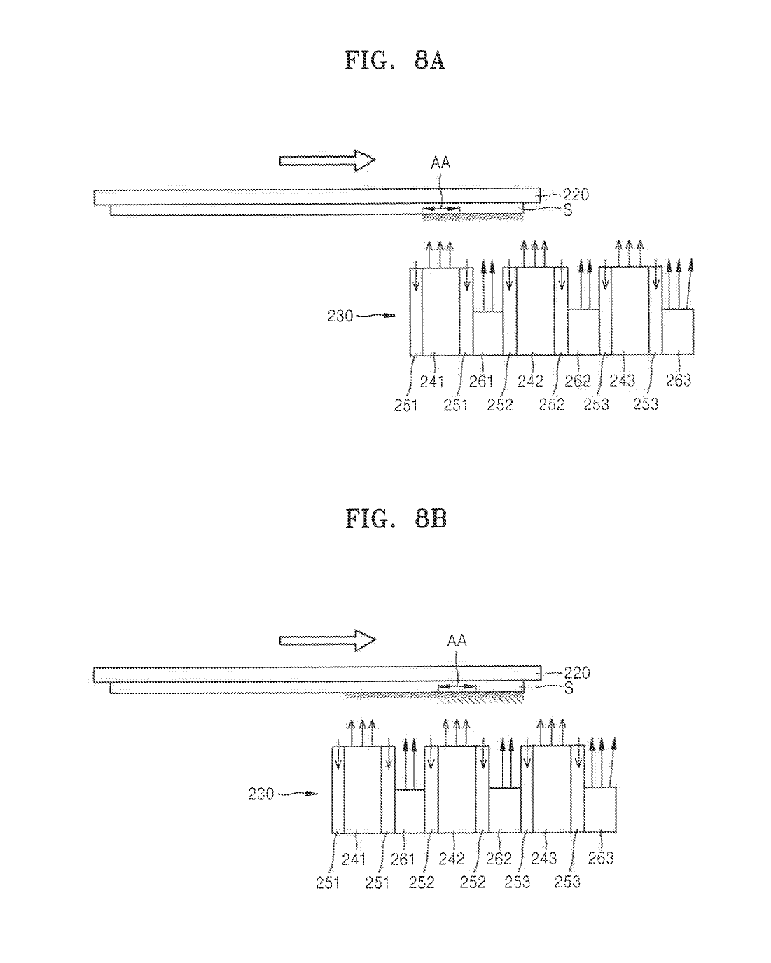

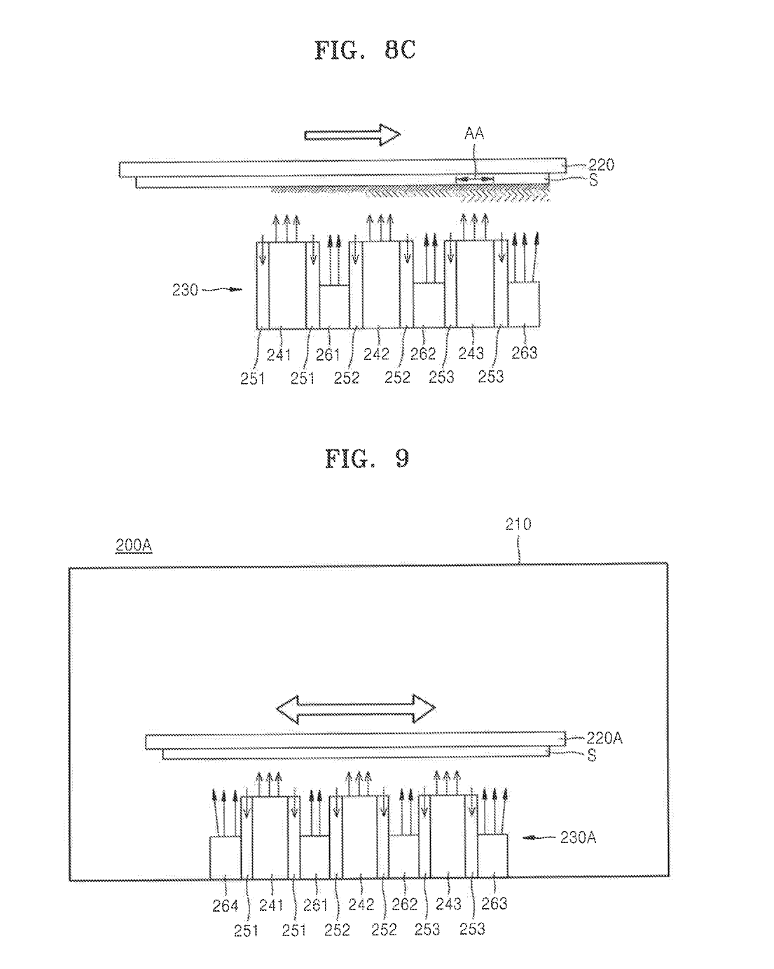

FIGS. 8A to 8C are schematic views of the stage 200 and the deposition module 230 of FIG. 7. A deposition process will be described below with reference to FIGS. 8A to 8C.

Referring to FIG. 8A, the first feeding unit 241 sprays a first raw material toward section AA. Part of the first raw material that is not deposited on the substrate S is discharged from the chamber 210 by the first discharge unit 251. As the stage 220 moves in a direction indicated by an arrow, section AA of the substrate S is positioned to face the first light exposure unit 261 and the first raw material deposited on section AA is cured by ultraviolet rays emitted by the first light exposure unit 261.

As the stage 220 continuously moves in the direction indicated by the arrow, section M of the substrate S is positioned to face a second feeding unit 242 as shown in FIG. 8B. The second feeding unit 242 sprays a second raw material onto the first raw material deposited on section AA of the substrate S. Part of the second raw material that is not deposited on section AA of the substrate S is discharged from the chamber 210 by the second discharge unit 252. As the stage 220 continuously moves in the direction indicated by the arrow, section AA of the substrate S is positioned to face a second light exposure unit 262 and the second raw material deposited on section AA is cured by ultraviolet rays that are emitted by the second light exposure unit 262.

As the stage 220 continuously moves in the direction indicated by the arrow, section AA of the substrate S is positioned to face a third feeding unit 243 as shown in FIG. 8C. The third feeding unit 243 sprays a third raw material onto the second raw material deposited on section AA of the substrate S. Part of the third raw material that is not deposited on section AA of the substrate S is discharged from the chamber 210 by the third discharge unit 253. As the stage 220 continuously moves in the direction indicated by the arrow, section AA of the substrate S is positioned to face a third light exposure unit 263 and the third raw material deposited on section AA is cured by ultraviolet rays that are emitted by the third light exposure unit 263. The first to third raw materials may be the same or different materials.

As described above, the deposition module 230 may perform the deposition, discharge, and curing processes several times by using the feeding units 241 to 243, the discharge units 251 to 253, and the light exposure units 261 to 263. Accordingly, it is possible to prevent the feeding units 241 to 243 from being clogged by performing the deposition, discharge, and curing processes several times. For example, when the thickness of a thin film to be deposited is large, such cyclic process may prevent a sprayed raw material from clogging the feeding units 241 to 243. Moreover, it is possible to decrease an amount of light exposure of each of the light exposure units 261 to 263, and thus, it is possible to complete curing without use of much electric power.

Although FIGS. 8A to 8C describe an exemplary embodiment where the stage 220 and the deposition module 230 move in one direction, the relative movement between the stage 220 and the deposition module 230 is not limited thereto. For example, the stage 220A may move in two directions relative to the deposition module 230A as shown in FIG. 9. In this case, since the position of the downstream part of the relative movement path varies according to a movement direction when the feeding units 241 to 243 are in reference positions, the light exposure units 261 to 264 are arranged at both sides of the feeding units 241 to 243.

For the convenience of description, the present invention is described how a deposition process using an exemplary deposition apparatus according to the present invention occurs on the section AA of the substrate S. Such deposition process may simultaneously occur at other sections of the substrate S in an exemplary deposition apparatus to increase the deposition efficiency. As shown in FIGS. 8A to 8C, the feeding units 241 to 243 each sprays a gaseous raw material toward its corresponding section of the substrate S at the same time.

The stages 220 and 220A are arranged in a lower part of a chamber and thus the deposition modules 230 and 230A may spray raw materials upwardly and cure them from the substrate S. The stages 220 and 220A are fixed and the deposition modules 230 and 230A move relative to the stages 220 and 220A. The present invention is not limited thereto, and the arrangements and relative movements of a stage and a deposition module may be changed.

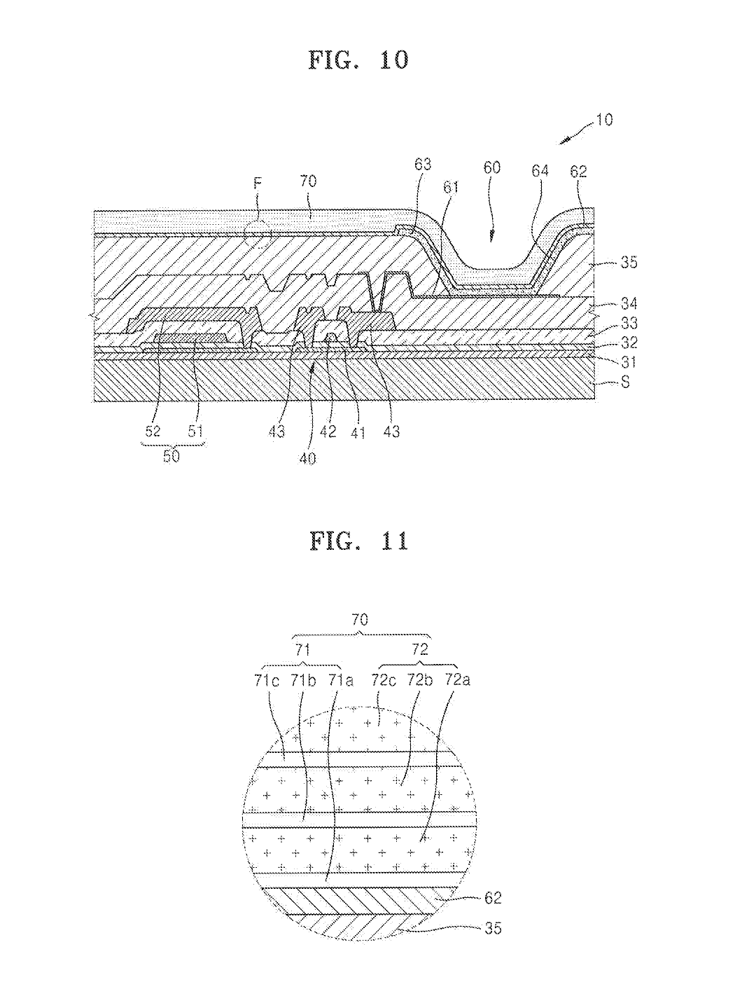

FIG. 10 is a schematic cross-sectional view of an organic light-emitting display apparatus that is manufactured using a deposition apparatus according to an exemplary embodiment of the present invention, and FIG. 11 is an expanded view of portion F of FIG. 10.

Referring to FIGS. 10 and 11, the organic light emitting display apparatus 10 is formed on a substrate S. The substrate S may be formed of a glass, plastic, or metal material.

The upper part of the substrate S is planar, and a buffer layer 31 that contains an insulating material to prevent moisture and foreign materials from permeating is formed on the substrate S.

A thin film transistor (TFT) 40, a capacitor 50, and an organic light emitting device 60 are formed on the buffer layer 31. The TFT 40 includes an active layer 41, a gate electrode 42, and source/drain electrodes 43. The light emitting device 60 includes a first electrode 61, a second electrode 62, and an intermediate layer 63.

For example, the active layer 41 is formed in a certain pattern on the buffer layer 31. The active layer 41 may contain an inorganic semiconductor material such as silicon, an organic semiconductor material, or an oxide semiconductor material, and may be formed by injecting a p-type or n-type dopant.

A gate insulating layer 32 is formed on the active layer 41. A gate electrode 42 is formed on the gate insulating layer 32 to match the active layer 41. An interlayer insulating layer 33 is formed to cover the gate electrode 42 and the source/drain electrodes 43 are formed on the interlayer insulting layer 33 to be in contact with a certain region of the active layer 41. A passivation layer 34 is formed to cover the source/drain electrodes 43 and a separate insulating layer be further formed on the passivation layer 34 to achieve planarization of the TFT 40.

A first electrode 61 is formed on the passivation layer 34. The first electrode 61 is formed to be electrically connected to any one of the source/drain electrodes 43. In addition, a pixel defining layer 35 is formed to cover the first electrode 61. An opening 64 is formed in the pixel defining layer 35, and the intermediate layer 63 including an organic light emitting layer is formed in the region defined by the opening 64. The second electrode 62 is formed on the intermediate layer 63.

An encapsulation layer 70 is formed on the second electrode 62. The encapsulation layer 70 may contain an organic material or an inorganic material and have a structure in which an organic material and an inorganic material are alternately stacked.

The encapsulation layer 70 may be formed by using an exemplary deposition apparatus according to the present invention. For example, the encapsulation layer 70 is formed when the substrate S passes through a chamber of an exemplary deposition apparatus according to the present invention.

The encapsulation layer 70 includes an inorganic layer 71 and an organic layer 72. The inorganic layer 71 includes a plurality of layers 71a to 71c, and the organic layer 72 includes a plurality of layers 72a to 72c. The organic layers 72a to 72c are formed using an exemplary deposition apparatus according to the present invention. For example, when the exemplary deposition apparatus corresponds to the deposition apparatus 200 of FIG. 7, the deposition apparatus 200 includes the feeding units 241 to 243, the discharge units 251 to 253, and the light exposure units 261 to 263 and the deposition processes are performed on the moving substrate S moves to form the organic layers 72a to 72c to in a desired thickness.

However, the present invention is not limited thereto and it is possible to form other insulating layers such as an inorganic layer 71, a buffer layer 31, a gate insulating layer 32, an interlayer insulating layer 33, a passivation layer 34, and a pixel defining layer 35 using an exemplary deposition apparatus according to the present invention. Various thin layers such as an active layer 41, a gate electrode 42, a source/drain electrode 43, a second electrode 61, an intermediate layer 63, and a second electrode 62 is also formed using an exemplary deposition apparatus according to the present invention.

Using a deposition apparatus according to the present invention increases the deposition efficiency in manufacturing an organic light-emitting display apparatus.

While the present invention has been shown and described with reference to exemplary embodiments thereof, it will be apparent to those of ordinary skill in the art that various changes in form and detail may be made therein without departing from the spirit and scope of the inventive concept as defined by the following claims.

What is claimed is:

1. A deposition apparatus comprising:
a stage configured to hold a substrate; and
a deposition module configured to face the substrate,
wherein the stage relatively moves in a direction relative to the deposition module, and the deposition module comprises:
a first feeding unit configured to spray a first raw material toward the substrate, and
a first light exposure unit disposed on at least one side of the first feeding unit and configured to provide light to the first raw material sprayed on the substrate,

2. The deposition apparatus of claim 1, further comprising a chamber, wherein the stage and the deposition module are positioned in the chamber, wherein the deposition module further comprises a first discharge unit interposed between the first feeding unit and the first light exposure unit and configured to discharge from the chamber some of the first raw material sprayed from the first feeding unit.

3. The deposition apparatus of claim 2, wherein the first light exposure unit is disposed in a downstream part of the direction in which the stage relatively moves relative to the deposition module.

4. The deposition apparatus of claim 2, wherein the first discharge unit and the first light exposure unit have different heights from each other.

5. The deposition apparatus of claim 4, wherein an end of the light exposure unit is further distant from the substrate than an end of the feeding unit.

6. The deposition apparatus of claim 2, wherein the deposition module further comprises:
a second feeding unit disposed on the first light exposure and configured to spray a second raw material toward the substrate; and
a second light exposure unit disposed on at least one side of the second feeding unit and configured to provide light to the second raw material sprayed on the substrate.

7. The deposition apparatus of claim 6, further comprising a second discharge unit interposed between the second feeding unit and the second light exposure unit and configured to discharge from the chamber some of the second raw material sprayed from the second feeding unit.

8. The deposition apparatus of claim 2, wherein the feeding unit sprays downwardly the first raw material toward the substrate.

9. The deposition apparatus of claim 2, wherein the feeding unit sprays upwardly the first raw material toward the substrate.

10. The deposition apparatus of claim 2, wherein the stage is fixed and the deposition module moves opposite to the direction.

11. The deposition apparatus of claim 2, wherein the deposition module is fixed and the stage moves in the direction.

12. The deposition apparatus of claim 2, wherein the direction includes at least one direction.

13. The deposition apparatus of claim 2, wherein the first raw material is substantially the same as the second raw material.

14. A deposition apparatus comprising:
a chamber;
a stage positioned in the chamber and configured to hold a substrate; and
a deposition module positioned in the chamber and configured to face the substrate,
wherein the stage relatively moves in a direction relative to the deposition module, and
the deposition module comprises:
a plurality of feeding units, each feeding unit configured to spray a raw material toward the substrate; and
a plurality of light exposure units, each light exposure unit configured to provide light to the raw material sprayed on the substrate,
wherein each feeding unit and each light exposure unit are alternately arranged along the direction.

15. The deposition apparatus of claim 14, wherein the deposition module further comprises a plurality of discharge units, each discharge unit interposed between each feeding unit and each light exposure unit and configured to discharge from the chamber some of the raw material sprayed from each feeding unit.

16. The deposition apparatus of claim 15, wherein each light exposure unit is disposed in a downstream part of the direction in which the stage relatively moves relative to the deposition module.

17. A method of manufacturing an organic light emitting display apparatus, the method comprising:
loading a substrate on a stage;
relatively moving the stage relative to a deposition module between time T1 and time T2, wherein the deposition module is configured to spray a first raw material and a second raw material to the substrate;
controlling the deposition module to spray, at the time T1, the first raw material on a first part of the substrate;
controlling the deposition module to spray, at the time T2, the second raw material on first material deposited on the first part of the substrate;
controlling the deposition module to spray, at the time T2, the first raw material on a second part of the substrate;
controlling the deposition module to provide, immediately after the time T1 and before the time T2, light to the first material deposited on the first part of the substrate, wherein the time Ti precedes the time T2.

18. The method of claim 17, wherein the first material is substantially the same as the second material.

19. The method of claim 17, further comprising:
relatively moving the stage relative to the deposition module between the time T2 and a time T3, wherein the deposition module is further configured to spray a third raw material to the substrate;
controlling the deposition module to spray, at the time T3, the first raw material on a third part of the substrate;
controlling the deposition module to spray, at the time T3, the second raw material on first raw material deposited on the second part of the substrate;
controlling the deposition module to spray, at the time T3, the third raw material on the second raw material on the first part of the substrate;
controlling the deposition module to provide, immediately after the time T2 and before the time T3, light to the first raw material deposited on the third part of the substrate and the second raw material deposited on the second part,
wherein the time T2 precedes the time T3.

20. The method of claim 19, wherein the first raw material, the second raw material, and the third raw material are substantially the same as each other.
